(19) United States
(12) Patent Application Publication
(10) Pub. No.: US 2025/0171297 A1
(43) Pub. Date: May 29, 2025

(54) MEMS COMPONENT

(71) Applicant: Robert Bosch GmbH, Stuttgart (DE)

(72) Inventors: Christoph Schelling, Stuttgart (DE); Jochen Reinmuth, Reutlingen (DE)

(21) Appl. No.: 18/949,225

(22) Filed: Nov. 15, 2024

(30) Foreign Application Priority Data
Nov. 23, 2023 (DE) 10 2023 211 678.2

(51) Int. Cl. B81B 3/00; G01L 9/00; H04R 19/02; H04R 19/04

(52) U.S. Cl. CPC B81B 3/007; B81B 3/0051; G01L 9/0005; H04R 19/02; H04R 19/04; B81B 2201/0257; B81B 2201/0264; B81B 2203/0127; B81B 2203/04; H04R 2201/003

(57) ABSTRACT

A MEMS component. The MEMS component includes: a substrate having a cavity and a base, an interaction element arranged above the cavity and connected to the base, including a bending beam, a boundary layer at a distance from the bending beam via connecting elements and defining a hollow space with the bending beam, and a backplate within the hollow space, the backplate being stiffer in relation to the boundary layer and the bending beam, at least one electrode, which forms a readable capacitance with a back electrode of the backplate, to capacitively detect a deflection of at least one of the bending beam, the connecting elements and the boundary layer, at least one stop element, configured to be displaced into a mechanical stop.

### FIELD

The present invention relates to a MEMS component, in particular an acoustic transducer or a pressure sensor.

### BACKGROUND INFORMATION

European Patent No. EP 2 664 058 B1 describes a micromechanical component.

European Patent No. EP 3 568 595 B1 describes a micromechanical device.

China Patent Application No. CN 1 14 885 264 A1 describes a microphone.

China Utility Model CN 2 16 852 338 U describes a microelectromechanical microphone.

Capacitive MEMS microphones are particularly efficient in terms of signal-to-noise ratio, energy consumption and processability. This has led to a widespread displacement of electret microphones by MEMS microphones.

The development of MEMS microphones with a dual membrane has further significantly improved the signal-to-noise ratio. In this concept, the fluidic damping between the rigid back electrode (backplate) and the movable back-pressure membrane is almost completely eliminated. This is achieved in that the backplate is mounted in a negative-pressure region between two coupled membranes.

U.S. Pat. Nos. 9,181,080 and 9,986,344 describes two such double-membrane microphones. The disadvantage of this arrangement is the high mechanical stiffness of the double-membrane structure, which limits its deflection and thus its sensitivity and signal-to-noise ratio.

### SUMMARY

The present invention is based on the object of providing a MEMS component.

This object may achieved by means of the subject matter according to the present invention. Advantageous embodiments of the present invention are disclosed herein.

According to a first aspect of the present invention, a MEMS component is provided, in particular an acoustic transducer or a pressure sensor. According to an example embodiment of the present invention, the MEMS component comprises:
a substrate having a cavity and a base,
an interaction element arranged above the cavity and connected to the base,
wherein the interaction element comprises a bending beam, a boundary layer arranged at a distance from the bending beam via connecting elements and defining a hollow space with the bending beam, and a backplate located within the hollow space, which comprises a back electrode, wherein the backplate is designed to be stiffer in relation to the boundary layer and the bending beam,
at least one electrode, which forms one or more readable capacitances with the back electrode of the backplate, in order to capacitively detect a deflection of at least one of the bending beam and the connecting elements and the boundary layer,
at least one stop element, which is configured to be displaced into a mechanical stop, wherein the stop element in the stop causes at least one fluid flow resistance, in particular a fluid seal, between the cavity on a side facing the substrate and a volume on a side of the hollow space facing away from the substrate.

The present invention is based on and includes the finding that the above object is achieved by providing an interaction element that is arranged above the cavity. Furthermore, at least one stop element is provided, which can be displaced into a mechanical stop. If the stop element is located in the mechanical stop, this causes at least one fluid flow resistance, in particular a fluid seal, between the cavity on a side facing the substrate and a volume on a side of the hollow space facing away from the substrate. For example, there is negative pressure in the hollow space itself. The stop element comprises, for example, the interaction element or the base or the substrate.

As a result, fluidic squeeze-film damping effects are avoided in an advantageous manner. In particular, as a result, gap noise during rapid differential pressure changes can be avoided in an advantageous manner. Furthermore, as a result, fluid leakage can be minimized in an advantageous manner. Furthermore, as a result, a deflection can be maximized in an advantageous manner. Furthermore, as a result, the sensitivity of the component can be maximized in an advantageous manner.

In particular, this provides a MEMS component that, compared to the aforementioned related art, makes possible a small size with the same performance or a higher performance with the same size.

The abbreviation “MEMS” stands for micro-electro-mechanical system.

In one example embodiment of the present invention, the MEMS component comprises an actuating device, which is configured to displace the stop element into the stop.

This, for example, results in the technical advantage that the stop element can be efficiently displaced.

In one example embodiment of the present invention, the MEMS component comprises a plurality of electrodes, which are formed and/or anchored in and/or on the bending beam and/or in and/or on the boundary layer and/or in and/or on the connecting elements in regions electrically insulated from one another.

Together with the backplate, these multiple electrodes form capacitances that can be read out in each case in order to capacitively detect a corresponding deflection of at least one of the bending beam and/or the connecting elements and/or the boundary layer relative to the backplate. In other words, these electrodes together with the backplate form readable capacitances and thus in an advantageous manner make possible a differential capacitive evaluation such as, for example, a measurement of a deflection of the interaction element relative to the backplate according to a differential pressure applied to the outside.

In one example embodiment of the MEMS component of the present, the electrodes are in each case designed as a planar electrode or as an electrode structure projecting into the hollow space.

This results in the technical advantage, for example, that high capacitance surface densities and thus higher sensitivities can be achieved. Smaller gap distances are possible with planar electrodes and larger electrode surfaces with projecting electrode structures.

In one example embodiment of the MEMS component of the present invention, the bending beam and/or the connecting elements and/or the boundary layer are in each case formed from an electrically non-conductive material, to which the electrode structure projecting into the hollow space is anchored.

As a result, in an advantageous manner, higher capacitance densities can be achieved and/or parasitic capacitances can be minimized, which makes possible a miniaturization or an increase in the sensitivity of the component.

In one example embodiment of the MEMS component of the present invention, the electrode structure(s) form(s) a plurality of segments electrically insulated from one another, in order to form independently readable capacitances with the backplate.

This results in the technical advantage, for example, that independently readable capacitances are formed or shaped such that differential capacitive evaluation is possible.

In one example embodiment of the MEMS component of the present invention, the boundary layer is anchored to the bending beam via boundary walls or the boundary layer is designed as a further bending beam and is connected directly to the base via an insulation layer.

These two options described above make possible a complete stress decoupling from the substrate or the base in an advantageous manner.

In one example embodiment of the MEMS component of the present invention, the connecting elements are formed from an electrically insulating material.

Evaluation electronics, which can be included, for example, in the MEMS component, ideally require the highest possible insulation resistance between all measuring electrodes, which is efficiently facilitated by the provision of connecting elements made of an electrically insulating material.

In one example embodiment of the MEMS component of the present invention, the connecting elements have a spring element that is mechanically anchored on one side to the bending beam and/or to the boundary layer or that is formed in two parts, wherein the two parts only come into contact with one another by a movement toward one another.

A one-sided connection of the connecting elements has the particular advantage that greater flexibility of the bending beams is possible and that no torque is transmitted. The two-part connection has the technical advantage, for example, that a particularly stable connection is achieved.

For example, a plurality of spring elements are provided. The above statements in connection with a spring element apply analogously to a plurality of spring elements. For example, internal spring elements can be mechanically anchored on one side of the bending beam and/or the boundary layer such that they only come into mechanical contact when gas pressure is applied to the outside.

In one example embodiment of the MEMS component of the present invention, the peripheral boundary wall of the hollow space has a laterally undulating profile.

This results in the technical advantage, for example, that the edge of the interaction element is stiffened to be resistant to collapse.

For example, a plurality of boundary walls running substantially next to one another can also be provided, and therefore the above designs in conjunction with one boundary wall also apply to a plurality of boundary walls and vice versa.

In other words, a plurality of boundary walls can be provided, which are laterally undulating, for example, and run next to one another.

In one example embodiment of the MEMS component of the present invention, the backplate is at least partially formed by an electrically conductive layer and/or by a dielectric.

This results in the technical advantage, for example, that the backplate is implemented efficiently and disruptive parasitic capacitances can be minimized.

For example, the backplate can be formed directly by a conductive layer and/or a dielectric.

In one example embodiment of the MEMS component of the present invention, the backplate comprises an electrically insulating carrier layer, on which one or more electrically insulated and electrically conductive regions are formed as back electrodes.

This results in the technical advantage, for example, that the backplate is implemented efficiently and disruptive parasitic capacitances can be minimized.

Thus, the backplate can, for example, consist of or be formed from an insulating carrier layer, for example silicon rich nitride of, for example, a thickness of 0.5 μm to 5 μm, and, for example, at least one electrode or a plurality of mutually insulated electrodes formed therein/thereon at least in some regions, which can, for example, also be arranged in a plurality of layers, made of, for example, polysilicon. Advantageously, leakage currents can be suppressed in this way and a measuring capacitance can be designed such that the measuring capacitance can be maximized and parasitic capacitances can be minimized.

In one example embodiment of the MEMS component of the present invention, the backplate has at least one flexible region at each of its anchoring regions, which is softer than a center region of the backplate.

This results in the technical advantage, for example, that an efficient decoupling between the boundary walls and the backplate can be achieved.

In particular, the backplate is designed in such a way that when the two coupled boundary layers, i.e., the boundary layer and the bending beam, are deflected, the backplate is deflected less than half the extent.

The bending of the two coupled boundary layers, i.e., the boundary layer and the bending beam, is transmitted to the backplate via the boundary walls. In order to achieve a large signal, i.e., a large deflection between the boundary layers of the backplate, a suitable mechanical decoupling is therefore particularly advantageous at this point and is thus provided in particular.

For example, the backplate has a flexible region at the edges toward the clamping region on the base, which flexible region is softer than the center region of the backplate. This can be carried out, for example, by structuring the backplate at the edges toward the clamping region by structuring springs in the backplate in this region and/or by using or providing different materials or designs of the backplate with different thicknesses between the inner region and the edges.

In other words, according to one example embodiment of the MEMS component of the present invention, the edge regions in each case have a spring structure in order to form the flexible region.

As already mentioned above, this results in the technical advantage of providing efficient mechanical decoupling.

Thus, according to the above statements, according to one example embodiment of the MEMS component of the present invention, the edge regions comprise a different material compared to the center region and/or wherein a thickness of a particular intermediate region between the edge regions and the center region is smaller than a thickness of the center region and/or wherein a tensile stress layer and/or a tensile stress structure is provided in a particular intermediate region between the edge regions and the center region, which generates or generate tensile stress relative to the center region.

This results in the technical advantage, for example, of providing a particularly efficient decoupling effect.

With regard to the tensile stress layer and the tensile stress structure described above, the following is added.

For example, a layer and/or structure is provided in an outer region of the backplate, which layer and/or structure generates tensile stress relative to an inner region. This layer or this structure is the aforementioned tensile stress layer or tensile stress structure.

This layer or structure generates tensile stress relative to an inner region.

The provision of such a layer or structure is particularly advantageous if a thin backplate with a thickness of less than 5 μm is provided. This means, for example, that the backplate has a thickness of less than 5 μm.

For example, in an outer region the backplate is made entirely or partially of tensile-stressed silicon nitride and in an inner region of the backplate it is made of polysilicon. This has the effect, for example, that the polysilicon region is under tensile stress, and thus behaves stiffly relative to bending that is transmitted to the backplate, for example, by the clamping of the backplate.

In one example embodiment of the MEMS component of the present invention, the stop element is formed by one of the boundary layer, the bending beam and the backplate.

In an advantageous manner of the present invention, the use of these layers reduces process complexity and increases the robustness of the component.

In one example embodiment of the MEMS component of the present invention, the stop element has a corrugation.

This results in the technical advantage, for example, that the flexibility of the stop element can be increased via the corrugation and/or a fluidic seal can be efficiently defined.

In one example embodiment of the MEMS component of the present invention, an insulating layer is provided between the stop element and the stop.

In an advantageous manner, the insulating layer serves to electrically insulate the electrode provided for engagement in the stop according to an exemplary embodiment, generally the actuating device.

In one example embodiment of the MEMS component of the present invention, a pressure equalization hole is provided in the stop element and/or a pressure equalization hole is provided as a cylinder recess through the hollow space.

This results in the technical advantage, for example, that a quasi-static differential pressure can be equalized and that a defined pressure equalization between the fluid volumes on both sides of the interaction element is made possible. As a result, a microphone signal can be independent of pressure fluctuations in the surrounding area.

In one example embodiment of the MEMS component of the present invention, the bending beam has one or two beam ends secured to the base or to the substrate.

This results in the technical advantage, for example, that the bending beam can be efficiently secured to the substrate.

In other words, the bending beam can have one or two beam ends secured to the substrate. In an advantageous manner, the securing of the beam ends defines the position of the bending beam and provides the necessary electrical supply line(s), for example. In addition, it is advantageous and provided, for example, to anchor the beam ends as softly as possible to the base via a spring structure in order to make the stop possible at low electrical voltage.

In one example embodiment of the MEMS component of the present invention, the boundary layer is designed as a further bending beam or as a membrane element.

This results in the technical advantage, for example, that the stress decoupling of the interaction element from the substrate or base can be achieved efficiently.

In one example embodiment of the MEMS component of the present invention, a further stop is provided on a side of the stop element opposite the stop.

This results in the technical advantage, for example, that the interaction element can be brought into a defined deflection/position and undesired movement beyond a deflection can be limited such that the robustness of the component can be efficiently increased.

In one example embodiment of the MEMS component of the present invention, the actuating device comprises at least one actuating electrode, which is configured to generate an electrical force in order to displace the stop element into the stop.

This results in the technical advantage, for example, that the stop element can be displaced efficiently into the stop and then forms a fluidic seal between the adjacent surrounding areas.

The wording “at least one” means “one or more.”

If the singular is used for the stop element in statements, the plural should always be understood and vice versa. This means that a plurality of stop elements can be provided.

The MEMS component is, for example, an acoustic transducer or a pressure sensor. The pressure sensor is a relative pressure sensor, for example. The acoustic transducer is a microphone, for example.

If only the word “component” is used, it should always be understood that this refers to the MEMS component.

The acoustic transducer is a loudspeaker, for example.

In one embodiment of the MEMS component, the stop element comprises the interaction element or the base or the substrate.

In the case of a plurality of stop elements, these in each case comprise, for example, the interaction element or the base or the substrate.

The embodiments and exemplary embodiments described here can be combined with one another in any way even if this is not explicitly described.

The present invention is explained in more detail below using preferred exemplary embodiments of the present invention.

### BRIEF DESCRIPTION OF THE DRAWINGS

FIG. 1 is a schematic cross-sectional view of a first MEMS component, according to an example embodiment of the present invention.

FIG. 2 is a schematic sectional view of the first MEMS component of FIG. 1.

FIG. 3 is a schematic cross-sectional view of a second MEMS component, according to an example embodiment of the present invention.

FIG. 4 is a schematic sectional view of the second MEMS component of FIG. 3.

FIG. 5 is a schematic cross-sectional view of a third MEMS component, as an example embodiment of the present invention.

FIG. 6 is a schematic sectional view of the third MEMS component of FIG. 5.

FIG. 7 is a schematic cross-sectional view of a fourth MEMS component, according to an example embodiment of the present invention.

FIG. 8 is a schematic cross-sectional view of a fifth MEMS component, according to an example embodiment of the present invention.

### DETAILED DESCRIPTION OF EXAMPLE EMBODIMENTS

In the following, the same reference signs can be used for identical features.

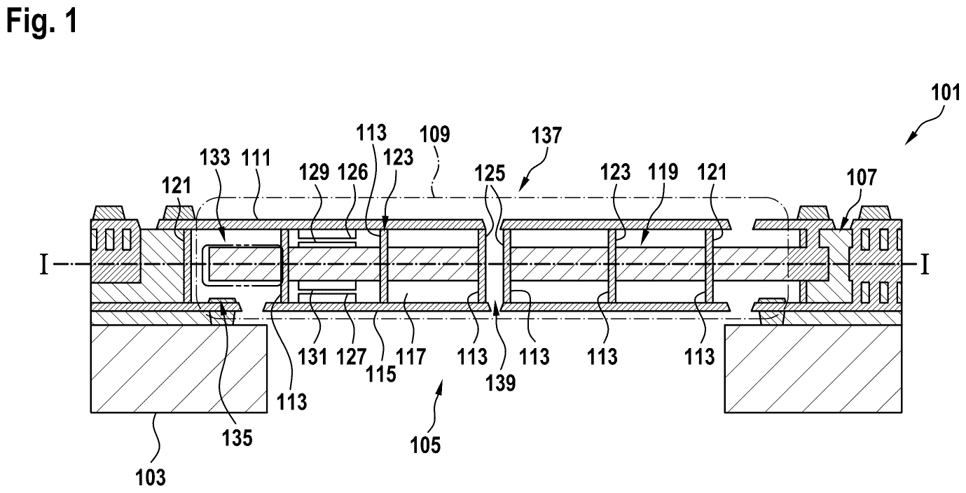

FIG. 1 is a schematic cross-sectional view of a first MEMS component 101.

The first MEMS component 101 comprises a substrate 103 having a cavity 105 and a base 107. Furthermore, the first MEMS component 101 comprises an interaction element 109 arranged above the cavity 105 and connected to the base 107. For the sake of clarity, insofar as the interaction element 109 comprises a plurality of elements, the elements belonging to the interaction element 109 are enclosed by a dashed line, which is marked with the reference sign 109. In other words, the interaction element 109 comprises a plurality of elements, as will be explained below.

The interaction element 109 comprises a bending beam 111. The interaction element 109 comprises a boundary layer 115 arranged at a distance from the bending beam 111 via connecting elements 113, which boundary layer defines a hollow space 117 with the bending beam 111.

A backplate 119 is arranged within the hollow space 117, which backplate is designed as a back electrode, wherein the backplate 119 is designed to be stiffer in relation to the boundary layer 115 and the bending beam 111.

According to the embodiment shown in FIG. 1, the first MEMS element 101 comprises a plurality of connecting elements 113. Here, outer connecting elements 121, 125 are provided as boundary walls and inner connecting elements 123 are provided as support elements.

This means that the connecting elements 123 are arranged between the two outer connecting elements 121, 125. The outer connecting elements 121, 125 are a boundary wall, for example. An inner connecting element 123 is formed here as a column. While the outer connecting element 121 is mechanically connected to the backplate 119, there is no mechanical coupling between the 15 Substitute Specification connecting elements 123, 125 and the backplate. Instead, these can move freely in through-openings in the backplate 119.

A first electrode 126 and a second electrode 127 are shown schematically. The first electrode 126 is located on the bending beam 111 on a side of the bending beam which faces the backplate 119. The second electrode 127 is located on the boundary layer 115 on a side of the boundary layer 115 which also faces the backplate 119.

Thus, the two electrodes 126, 127 in each case form a readable capacitance with the backplate 119 in order to capacitively detect a deflection of the bending beam 111 and the boundary layer 115 relative to the backplate. For this purpose, the backplate 119 has a first back electrode 129 and a second back electrode 131. These two back electrodes 129, 131 can also be referred to as counter-electrodes.

Here, the first back electrode 129 is arranged opposite the first electrode 126 on the backplate 119. The second back electrode 131 is arranged opposite the second electrode 127 on the backplate 119.

The interaction element 109 comprises a stop element 133, which is configured to be displaced into a mechanical stop 135, wherein the stop element 133 in the stop 135 creates at least one fluid flow resistance, in particular a fluid seal, between the cavity 105 on a side facing the substrate and a volume 137 on a side of the hollow space 117 facing away from the substrate.

Furthermore, a pressure equalization hole 139 is provided as a cylinder recess through the hollow space 117.

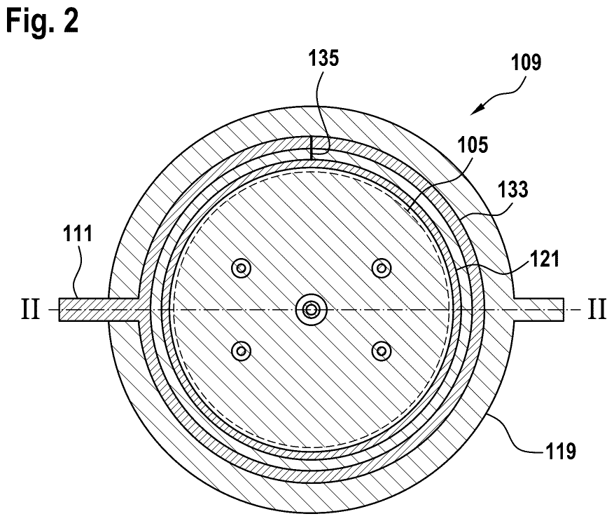

A section line I-I is furthermore shown, wherein the sectional view is shown according to section line I-I in FIG. 2. FIG. 2 shows a section line II-II, wherein a cross-section along section line II-II is shown in FIG. 1.

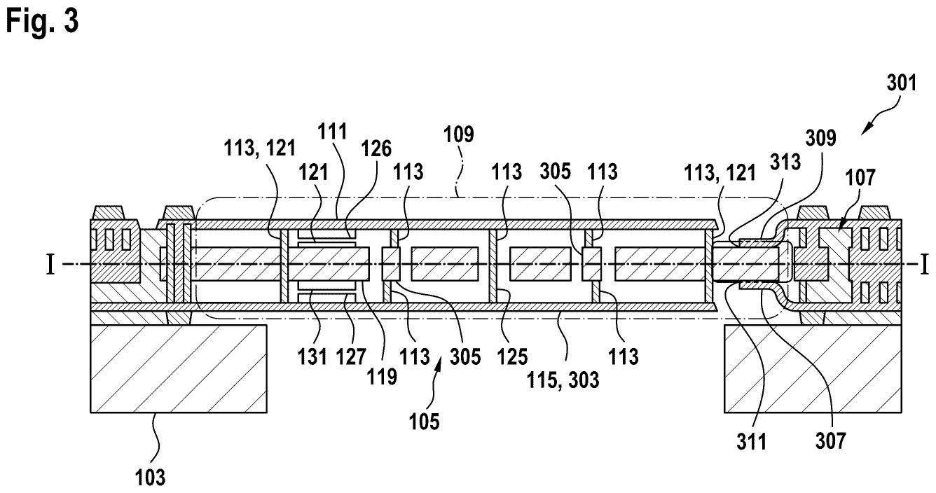

FIG. 3 is a schematic cross-sectional view of a second MEMS component 301.

In contrast to the first component 101 of FIG. 1, the boundary layer 115 of the second MEMS component 301 is designed as a further bending beam 303. In this respect, the element with the reference sign 115 is additionally marked with the reference sign 303.

Furthermore, two spring elements 305 are provided as connecting elements 113.

Furthermore, a first stop element 307 and a second stop element 309 are provided, which can abut against a first stop 311 and a second stop 313, respectively.

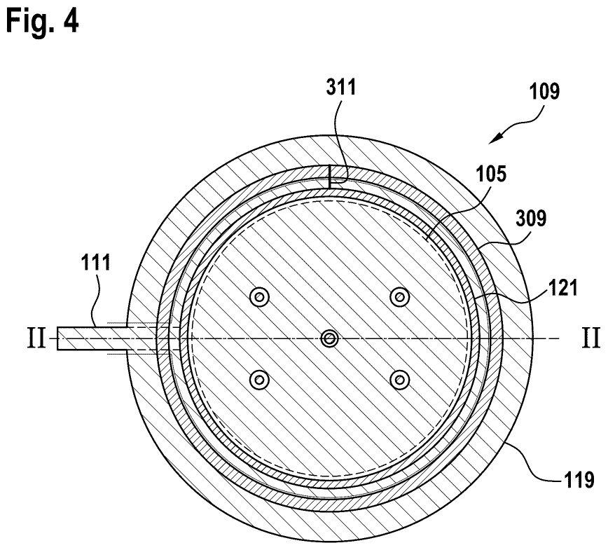

FIG. 4 is a schematic sectional view of the second MEMS component 301 of FIG. 3 along line I-I.

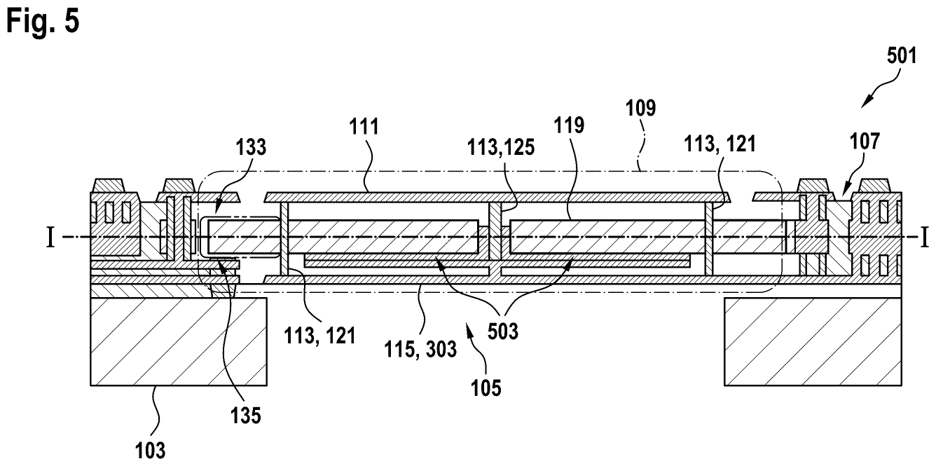

FIG. 5 is a schematic cross-sectional view of a third MEMS component 501.

The third MEMS component 501 has an electrode structure 503 suspended centrally on the connecting element 125, which electrode structure is provided as the back electrode of the backplate 119.

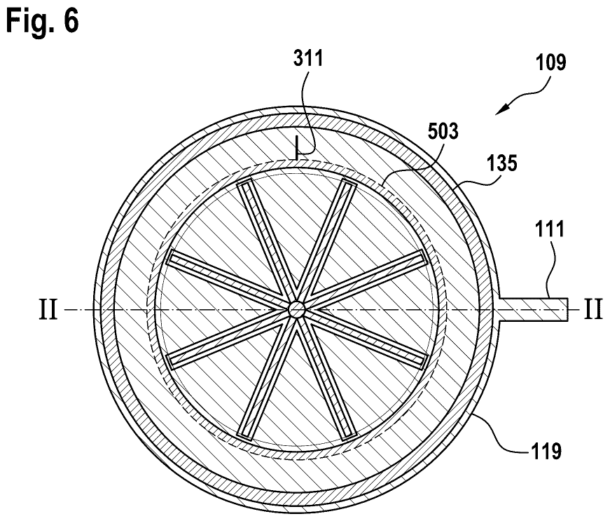

FIG. 6 is a schematic sectional view of the third MEMS component 501 of FIG. 5 along line I-I.

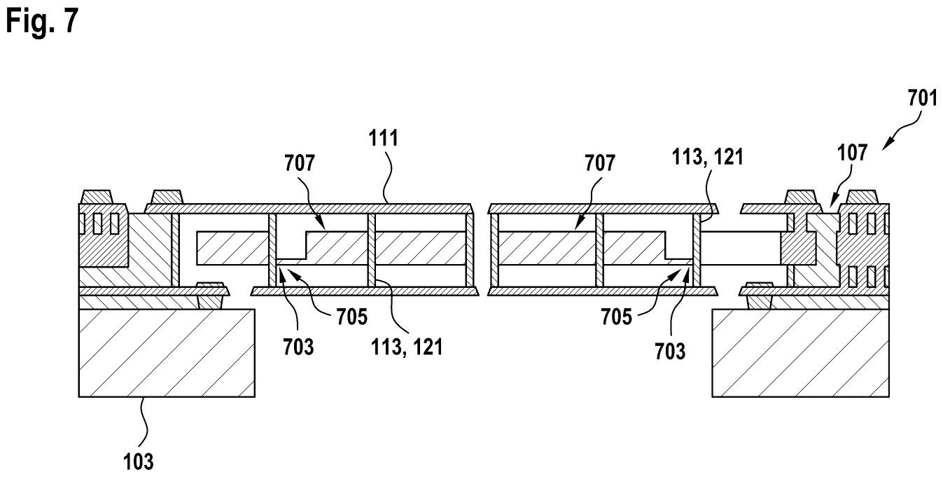

FIG. 7 is a schematic cross-sectional view of a fourth MEMS component 701. Here, the backplate 119 has different thicknesses in order to achieve decoupling between the outer boundary walls 121 and the backplate 119.

The reference sign 703 points to a location in which the backplate is clamped. The reference sign 705 points to a flexible region in the backplate compared to a stiff region 707 of the backplate 119.

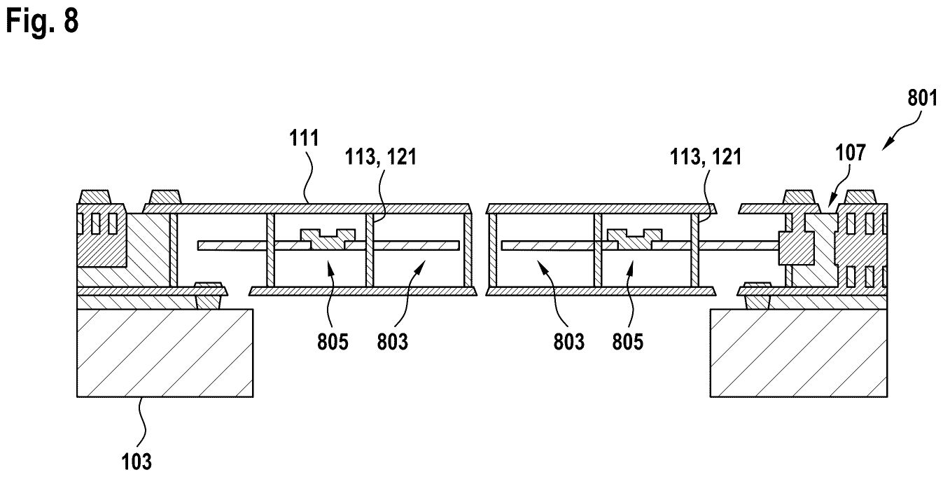

FIG. 8 shows a fifth MEMS component 801, wherein the backplate 119 has an outer ring that generates tensile stress on an inner region, and thus stiffens it in order to cause the outer boundary walls 121 to decouple from the backplate 119. The prestressed region is marked with the reference sign 803. The outer ring, which generates tensile stress, is marked with the reference sign 805. This outer ring 805 is the tensile stress structure designated above.

In summary, the concept described here is based in particular on the fact that the MEMS component has a flexible, exposed interaction element, in the interior of which a rigid backplate is located in a negative-pressure region. The recess in the substrate serves as a back volume, which reduces the damping effect of the back volume spring, or alternatively as a sound access opening. The engagement of the stop element with a stop, for example by means of electrodes as actuating means or as an actuating device, has the particular effect of creating a fluidic sealing effect, minimizing fluid leakage and maximizing deflection or sensitivity. Thus, in an advantageous manner, the sensitivity can be set at low frequencies in a targeted manner.

Electrodes can be formed or anchored in regions electrically insulated from one another in/on the bending beam, in/on the boundary layer and/or on connecting elements, wherein these can be realized as planar electrodes or as electrode structures projecting into the low-pressure region of the hollow space. Together with the backplate, these electrodes form readable capacitances and thus make possible a differential capacitive evaluation such as, e.g., the measurement of a deflection of the interaction element relative to the backplate according to a differential pressure applied to the outside.

The bending beam and the boundary layer can be formed by a non-conductive material, to which conductive immersion finger electrode structures pointing into the hollow space can be anchored. With this measure, for example, higher capacitance densities can be achieved than with planar electrodes, which makes possible a miniaturization or an increase in the sensitivity of the component.

The electrode structures anchored to the bending beam, to the boundary layer and/or to connecting elements can form a plurality of segments electrically insulated from one another and thus form independently readable capacitances.

The boundary layer can either be anchored to the bending beam via boundary walls or, alternatively, the boundary layer itself can be designed as a bending beam and connected directly to the base via an insulation layer. Both allow complete stress decoupling from the substrate or the base region.

The connecting elements (outer boundary walls, inner spring elements) can consist at least partially of an insulating material. Ideally, the evaluation electronics require the highest possible insulation resistance between all measuring electrodes, which is facilitated in this way.

Internal spring elements can be mechanically anchored on one side of the bending beam and/or the boundary layer such that they only come into mechanical contact when gas pressure is applied to the outside. Alternatively, the spring element can consist of two parts, which also only come into contact when gas pressure is applied to the outside. A one-sided connection of the support elements has the advantage that greater flexibility of the bending beams is possible and no torque is transmitted.

The peripheral boundary walls can be undulating, in particular laterally. This primarily serves to provide an edge that is resistant to collapse.

The backplate can be formed directly by a conductive layer and/or a dielectric. Alternatively, the backplate can consist of an insulating carrier layer such as, e.g., Si-rich nitride of a thickness of 0.5 . . . 5 μm and at least one electrode or a plurality of mutually insulated electrodes (also in a plurality of layers) formed thereon at least in some regions, which are made of, e.g., polySi. Advantageously, leakage currents can be suppressed in this manner and the measuring capacitance can be designed such that the measuring capacitance is maximized and parasitic capacitances are minimized.

The backplate can have corresponding through-openings for connecting elements and, if necessary, immersion finger electrodes. The through-openings decouple the backplate from the movement of the bending beams. The spring elements prevent the upper and lower boundary layers from collapsing onto the backplate. In addition, the boundary walls and spring elements connect the bending beam and the boundary layer and make their synchronous movement possible.

The stop element can, for example, be formed from parts of at least one of the boundary layer, the bending beam layer or the backplate layers and have corrugations. The use of these layers reduces process complexity and increases the robustness of the component. Corrugations can either increase the flexibility of the stop element or define the fluid seal.

An insulating layer can be located between the stop element and the stops. It serves for electrical insulation of the actuating means/electrodes required for engagement in the stop.

For an acoustic transducer (microphone, loudspeaker), a cylinder recess and/or a pressure equalization hole and/or pressure equalization gap can be provided either in the region of the hollow space and/or in the region of the support seal. This is necessary to be able to compensate for a quasi-static differential pressure and to make possible a defined pressure equalization between the fluid volumes on both sides of the interaction element. The microphone signal is thereby independent of pressure fluctuations in the surrounding area.

The bending beam(s) can have one or two beam ends secured to the substrate. The securing of the beam ends defines the position and provides the necessary electrical supply line(s). In addition, it is advantageous if this is anchored as softly as possible to the base via a spring structure in order to make possible the stop at low voltage.

The boundary layer can be designed as a membrane element or also as a bending beam. Both variants advantageously make possible the stress decoupling of the interaction element from the substrate/base.

A second stop on the side of the stop element opposite the first stop can be provided in order to limit undesired movement beyond a deflection and to increase the robustness of the component.

1. A MEMS component (101, 301, 501, 701, 801), in particular an acoustic transducer or a pressure sensor, comprising:
a substrate (103) having a cavity (105) and a base (107), an interaction element (109) arranged above the cavity (105) and connected to the base (107),
wherein the interaction element (109) comprises a bending beam (111),
a boundary layer (115) arranged at a distance from the bending beam (111) via connecting elements and defining a hollow space (113) with the bending beam (111), and
a backplate (119) located within the hollow space (113), which comprises a back electrode, wherein the backplate (119) is designed to be stiffer in relation to the boundary layer (115) and the bending beam (111),
at least one electrode, which forms a readable capacitance with the back electrode of the backplate (119), in order to capacitively detect a deflection of at least one of the bending beam (111), the connecting elements and the boundary layer (115),
at least one stop element (133), which is configured to be displaced into a mechanical stop (135), wherein the stop element (133) in the stop (135) creates at least one fluid flow resistance, in particular a fluid seal, between the cavity (105) on a side facing the substrate and a volume on a side of the hollow space (113) facing away from the substrate.

2. The MEMS component (101, 301, 501, 701, 801) according to claim 1, comprising an actuating device, which is configured to displace the stop element (133) into the stop (135).

3. The MEMS component (101, 301, 501, 701, 801) according to claim 1 or 2, comprising a plurality of electrodes, which are formed and/or anchored in and/or on the bending beam (111) and/or in and/or on the boundary layer (115) and/or in and/or on the connecting elements in regions electrically insulated from one another.

4. The MEMS component (101, 301, 501, 701, 801) according to claim 3, wherein the electrodes are in each case formed as a planar electrode or as an immersion finger electrode structure projecting into the hollow space (113).

5. The MEMS component (101, 301, 501, 701, 801) according to claim 4, wherein the bending beam (111) and/or the boundary layer (115) are in each case formed from an electrically non-conductive material, to which the electrode structures projecting into the hollow space (113) are anchored.

6. The MEMS component (101, 301, 501, 701, 801) according to one of claims 3 to 5, wherein the one or more electrode structures form a plurality of segments electrically insulated from one another, in order to form independently readable capacitances with the backplate (119).

7. The MEMS component (101, 301, 501, 701, 801) according to one of the preceding claims, wherein the boundary layer (115) is anchored to the bending beam (111) via boundary walls or wherein the boundary layer (115) is designed as a further bending beam (111) and is connected directly to the base (107) via an insulation layer.

8. The MEMS component (101, 301, 501, 701, 801) according to one of the preceding claims, wherein the connecting elements are formed from an electrically insulating material.

9. The MEMS component (101, 301, 501, 701, 801) according to one of the preceding claims, wherein the connecting elements have a spring element that is mechanically anchored on one side to the bending beam (111) and/or to the boundary layer (115) or that is formed in two parts, wherein the two parts only come into contact with one another by a movement toward one another.

10. The MEMS component (101, 301, 501, 701, 801) according to one of the preceding claims, wherein the boundary wall (121) is laterally undulating.

11. The MEMS component (101, 301, 501, 701, 801) according to one of the preceding claims, wherein the backplate (119) is formed by an electrically conductive layer and/or by a dielectric.

12. The MEMS component (101, 301, 501, 701, 801) according to one of the preceding claims, wherein the backplate (119) comprises an electrically insulating carrier layer on which one or more electrically insulated and electrically conductive regions are formed as back electrodes.

13. The MEMS component (101, 301, 501, 701, 801) according to one of the preceding claims, wherein the backplate (119) has a flexible region at each of its edge regions, which is softer than a center region of the backplate (119).

14. The MEMS component (101, 301, 501, 701, 801) according to claim 13, wherein the edge regions in each case have a spring structure in order to form the flexible region.

15. The MEMS component (101, 301, 501, 701, 801) according to claim 13 or 14, wherein the edge regions comprise a different material compared to the center region and/or wherein a thickness of a particular intermediate region between the edge regions and the center region is smaller than a thickness of the center region and/or wherein a tensile stress layer and/or a tensile stress structure (805) is provided in a particular intermediate region between the edge regions and the center region, which generates or generate tensile stress relative to the center region.

16. The MEMS component (101, 301, 501, 701, 801) according to one of the preceding claims, wherein the stop element (133) comprises parts of one of the boundary layer (115), the bending beam (111) and the backplate (119).

17. The MEMS component (101, 301, 501, 701, 801) according to one of the preceding claims, wherein the stop element (133) has a corrugation.

18. The MEMS component (101, 301, 501, 701, 801) according to one of the preceding claims, wherein an insulating layer is provided between the stop element (133) and the stop (135).

19. The MEMS component (101, 301, 501, 701, 801) according to one of the preceding claims, wherein a pressure equalization hole is provided in the stop element (133) and/or wherein a pressure equalization hole (139) is provided as a cylinder recess through the hollow space (113).

20. The MEMS component (101, 301, 501, 701, 801) according to one of the preceding claims, wherein the bending beam (111) has one or two beam ends secured to the substrate (103).

21. The MEMS component (101, 301, 501, 701, 801) according to one of the preceding claims, wherein the boundary layer (115) is designed as a further bending beam (111) or as a membrane element.

22. The MEMS component (101, 301, 501, 701, 801) according to one of the preceding claims, wherein a further stop (135) is provided on a side of the stop element (133) opposite the stop (135).

23. The MEMS component (101, 301, 501, 701, 801) according to one of the preceding claims to the extent that it refers back to claim 2, wherein the actuating device comprises at least one actuating electrode, which is configured to generate an electrical force in order to displace the stop element (133) into the stop (135).
